(19) United States
(12) Patent Application Publication
(10) Pub. No.: US 2024/0184947 A1
(43) Pub. Date: Jun. 6, 2024

(54) ATTRIBUTION OF REPRODUCIBILITY RESULTS OF AUTONOMOUS VEHICLE SUBSYSTEM

(71) Applicant: GM Cruise Holdings LLC, San Francisco, CA (US)

(72) Inventors: Pragati Agarwal, Fremont, CA (US); Luke Murchison, Belmont, CA (US)

(21) Appl. No.: 18/074,016

(22) Filed: Dec. 2, 2022

(51) Int. Cl. G06F 30/20; B60W 60/00

(52) U.S. Cl. CPC G06F 30/20; B60W 60/001; B60W 2554/4046

(57) ABSTRACT

Aspects of the subject technology relate to systems, methods, and computer-readable media for troubleshooting a baseline simulation. A method can include accessing captured real-world data of performed behaviors of an autonomous vehicle in operation and running input data through a simulation template as part of a baseline simulation. The method can also include identifying a divergence of the baseline simulation between the performed behaviors of the AV and simulated behaviors in the baseline simulation of the AV. The method can include running the input data through a modified simulation template and identifying a divergence of the modified simulation between the performed behaviors of the AV and simulated behaviors in the modified simulation of the AV. The method can include troubleshooting the baseline simulation based on a comparison between the divergence of the modified simulation and the divergence of the baseline simulation.

### BACKGROUND

### 1. Technical Field

The present disclosure generally relates to identifying a divergence of a modified simulation between the performed behaviors of an autonomous vehicle and simulated behaviors in the modified simulation of the autonomous vehicle and, more specifically, to troubleshooting a baseline simulation based on a comparison between the divergence of the modified simulation and the divergence of the baseline simulation.

### 2. Introduction

An autonomous vehicle is a motorized vehicle that can navigate without a human driver. An exemplary autonomous vehicle can include various sensors, such as a camera sensor, a light detection and ranging (LIDAR) sensor, and a radio detection and ranging (RADAR) sensor, amongst others. The sensors collect data and measurements that the autonomous vehicle can use for operations such as navigation. The sensors can provide the data and measurements to an internal computing system of the autonomous vehicle, which can use the data and measurements to control a mechanical system of the autonomous vehicle, such as a vehicle propulsion system, a braking system, or a steering system. Typically, the sensors are mounted at fixed locations on the autonomous vehicles.

### BRIEF DESCRIPTION OF THE DRAWINGS

The various advantages and features of the present technology will become apparent by reference to specific implementations illustrated in the appended drawings. A person of ordinary skill in the art will understand that these drawings only show some examples of the present technology and would not limit the scope of the present technology to these examples. Furthermore, the skilled artisan will appreciate the principles of the present technology as described and explained with additional specificity and detail through the use of the accompanying the drawings in which:

FIG. 1 illustrates an example system environment that can be used to facilitate autonomous vehicle (AV) dispatch and operations, according to some examples of the present disclosure;

FIG. 2 illustrates a conceptual flow of an AV software stack, according to some examples of the present disclosure;

FIG. 3 illustrates a flowchart for an example method of troubleshooting a simulation based on a comparison between the divergence of a modified simulation and the divergence of a baseline simulation, according to some examples of the present disclosure;

FIG. 4 illustrates a conceptual flow of incrementing a subset of a simulated AV software stack, according to another example of the present disclosure; and

FIG. 5 illustrates an example processor-based system with which some aspects of the subject technology can be implemented, according to some examples of the present disclosure.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a more thorough understanding of the subject technology. However, it will be clear and apparent that the subject technology is not limited to the specific details set forth herein and may be practiced without these details. In some instances, structures and components are shown in block diagram form in order to avoid obscuring the concepts of the subject technology.

One aspect of the present technology is the gathering and use of data available from various sources to improve quality and experience. The present disclosure contemplates that in some instances, this gathered data may include personal information. The present disclosure contemplates that the entities involved with such personal information respect and value privacy policies and practices.

A software stack can be used to control an autonomous vehicle. In particular, a software stack can include various dependent processes that can be implemented to control an autonomous vehicle. In developing autonomous vehicles, numerous tests are run that generate a large amount of data through the implementation of the software stack. It can be advantageous to run simulations of the autonomous vehicle operating in simulated environments in order to generate additional data. Collection of data through simulations is a less time consuming and more cost effective method than real-world data collection.

Improving simulation results to more effectively represent real world results is a rigorous process from both a time perspective and a resource perspective. Specifically, often a simulation can be rerun from end to end to identify a divergence between the simulation results and the real world results. Further, one or more experts have to manually inspect the results of each process in the stack from end to end to diagnose the cause of the divergence. This is problematic due to the large amount of consumed resources and time. Specifically, in the autonomous vehicle space and with reference to testing, due to both the large amount of data included in running a software stack for a test, and the sheer volume of tests that are run, it is very difficult to efficiently identify divergences between simulation results and real world results.

The disclosed technology addresses the problems associated with improving results obtained from running simulations of an autonomous vehicle (AV) in a simulated environment. For example, while navigating a real-world environment, an AV can capture real-world data and record the performed behaviors of the AV navigating this real-world environment. Subsequently, a simulation based on the captured real-world environment data can be run wherein a simulated AV is dispatched within this simulated environment. The simulated operation of the AV within this simulated environment can then be compared to the actual performed behaviors of the AV that previously navigated this real-world environment to determine whether there is a divergence between the operation of the simulated AV and the performed behaviors of real-world AV.

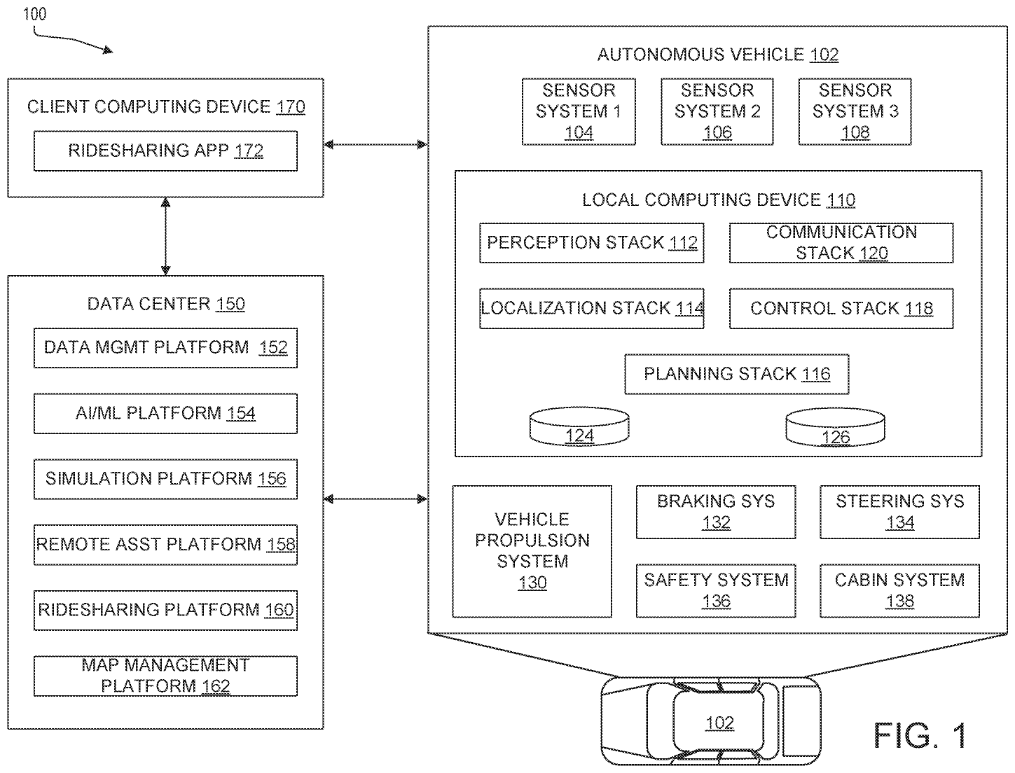

FIG. 1 illustrates an example of an AV management system 100. One of ordinary skill in the art will understand that, for the AV management system 100 and any system discussed in the present disclosure, there can be additional or fewer components in similar or alternative configurations. The illustrations and examples provided in the present disclosure are for conciseness and clarity. Other embodiments may include different numbers and/or types of elements, but one of ordinary skill the art will appreciate that such variations do not depart from the scope of the present disclosure.

In this example, the AV management system 100 includes an AV 102, a data center 150, and a client computing device 170. The AV 102, the data center 150, and the client computing device 170 can communicate with one another over one or more networks (not shown), such as a public network (e.g., the Internet, an Infrastructure as a Service (IaaS) network, a Platform as a Service (PaaS) network, a Software as a Service (SaaS) network, another Cloud Service Provider (CSP) network, etc.), a private network (e.g., a Local Area Network (LAN), a private cloud, a Virtual Private Network (VPN), etc.), and/or a hybrid network (e.g., a multi-cloud or hybrid cloud network, etc.).

AV 102 can navigate about roadways without a human driver based on sensor signals generated by multiple sensor systems 104, 106, and 108. The sensor systems 104-108 can include different types of sensors and can be arranged about the AV 102. For instance, the sensor systems 104-108 can comprise Inertial Measurement Units (IMUs), cameras (e.g., still image cameras, video cameras, etc.), light sensors (e.g., LIDAR systems, ambient light sensors, infrared sensors, etc.), RADAR systems, a Global Navigation Satellite System (GNSS) receiver, (e.g., Global Positioning System (GPS) receivers), audio sensors (e.g., microphones, Sound Navigation and Ranging (SONAR) systems, ultrasonic sensors, etc.), engine sensors, speedometers, tachometers, odometers, altimeters, tilt sensors, impact sensors, airbag sensors, seat occupancy sensors, open/closed door sensors, tire pressure sensors, rain sensors, and so forth. For example, the sensor system 104 can be a camera system, the sensor system 106 can be a LIDAR system, and the sensor system 108 can be a RADAR system. Other embodiments may include any other number and type of sensors.

AV 102 can also include several mechanical systems that can be used to maneuver or operate AV 102. For instance, the mechanical systems can include vehicle propulsion system 130, braking system 132, steering system 134, safety system 136, and cabin system 138, among other systems. Vehicle propulsion system 130 can include an electric motor, an internal combustion engine, or both. The braking system 132 can include an engine brake, a wheel braking system (e.g., a disc braking system that utilizes brake pads), hydraulics, actuators, and/or any other suitable componentry configured to assist in decelerating AV 102. The steering system 134 can include suitable componentry configured to control the direction of movement of the AV 102 during navigation. Safety system 136 can include lights and signal indicators, a parking brake, airbags, and so forth. The cabin system 138 can include cabin temperature control systems, in-cabin entertainment systems, and so forth. In some embodiments, the AV 102 may not include human driver actuators (e.g., steering wheel, handbrake, foot brake pedal, foot accelerator pedal, turn signal lever, window wipers, etc.) for controlling the AV 102. Instead, the cabin system 138 can include one or more client interfaces (e.g., Graphical User Interfaces (GUIs), Voice User Interfaces (VUIs), etc.) for controlling certain aspects of the mechanical systems 130-138.

AV 102 can additionally include a local computing device 110 that is in communication with the sensor systems 104-108, the mechanical systems 130-138, the data center 150, and the client computing device 170, among other systems. The local computing device 110 can include one or more processors and memory, including instructions that can be executed by the one or more processors. The instructions can make up one or more software stacks or components responsible for controlling the AV 102; communicating with the data center 150, the client computing device 170, and other systems; receiving inputs from riders, passengers, and other entities within the AV's environment; logging metrics collected by the sensor systems 104-108; and so forth. In this example, the local computing device 110 includes a perception stack 112, a mapping and localization stack 114, a planning stack 116, a control stack 118, a communications stack 120, an High Definition (HD) geospatial database 122, and an AV operational database 124, among other stacks and systems.

Perception stack 112 can enable the AV 102 to “see” (e.g., via cameras, LIDAR sensors, infrared sensors, etc.), “hear” (e.g., via microphones, ultrasonic sensors, RADAR, etc.), and “feel” (e.g., pressure sensors, force sensors, impact sensors, etc.) its environment using information from the sensor systems 104-108, the mapping and localization stack 114, the HD geospatial database 122, other components of the AV, and other data sources (e.g., the data center 150, the client computing device 170, third-party data sources, etc.). The perception stack 112 can detect and classify objects and determine their current and predicted locations, speeds, directions, and the like. In addition, the perception stack 112 can determine the free space around the AV 102 (e.g., to maintain a safe distance from other objects, change lanes, park the AV, etc.). The perception stack 112 can also identify environmental uncertainties, such as where to look for moving objects, flag areas that may be obscured or blocked from view, and so forth.

Mapping and localization stack 114 can determine the AV's position and orientation (pose) using different methods from multiple systems (e.g., GPS, IMUs, cameras, LIDAR, RADAR, ultrasonic sensors, the HD geospatial database 122, etc.). For example, in some embodiments, the AV 102 can compare sensor data captured in real-time by the sensor systems 104-108 to data in the HD geospatial database 122 to determine its precise (e.g., accurate to the order of a few centimeters or less) position and orientation. The AV 102 can focus its search based on sensor data from one or more first sensor systems (e.g., GPS) by matching sensor data from one or more second sensor systems (e.g., LIDAR). If the mapping and localization information from one system is unavailable, the AV 102 can use mapping and localization information from a redundant system and/or from remote data sources.

The planning stack 116 can determine how to maneuver or operate the AV 102 safely and efficiently in its environment. For example, the planning stack 116 can receive the location, speed, and direction of the AV 102, geospatial data, data regarding objects sharing the road with the AV 102 (e.g., pedestrians, bicycles, vehicles, ambulances, buses, cable cars, trains, traffic lights, lanes, road markings, etc.) or certain events occurring during a trip (e.g., an Emergency Vehicle (EMV) blaring a siren, intersections, occluded areas, street closures for construction or street repairs, Double-Parked Vehicles (DPVs), etc.), traffic rules and other safety standards or practices for the road, user input, and other relevant data for directing the AV 102 from one point to another. The planning stack 116 can determine multiple sets of one or more mechanical operations that the AV 102 can perform (e.g., go straight at a specified speed or rate of acceleration, including maintaining the same speed or decelerating; turn on the left blinker, decelerate if the AV is above a threshold range for turning, and turn left; turn on the right blinker, accelerate if the AV is stopped or below the threshold range for turning, and turn right; decelerate until completely stopped and reverse; etc.), and select the best one to meet changing road conditions and events. If something unexpected happens, the planning stack 116 can select from multiple backup plans to carry out. For example, while preparing to change lanes to turn right at an intersection, another vehicle may aggressively cut into the destination lane, making the lane change unsafe. The planning stack 116 could have already determined an alternative plan for such an event, and upon its occurrence, help to direct the AV 102 to go around the block instead of blocking a current lane while waiting for an opening to change lanes.

The control stack 118 can manage the operation of the vehicle propulsion system 130, the braking system 132, the steering system 134, the safety system 136, and the cabin system 138. The control stack 118 can receive sensor signals from the sensor systems 104-108 as well as communicate with other stacks or components of the local computing device 110 or a remote system (e.g., the data center 150) to effectuate operation of the AV 102. For example, the control stack 118 can implement the final path or actions from the multiple paths or actions provided by the planning stack 116. This can involve turning the routes and decisions from the planning stack 116 into commands for the actuators that control the AV's steering, throttle, brake, and drive unit.

The communication stack 120 can transmit and receive signals between the various stacks and other components of the AV 102 and between the AV 102, the data center 150, the client computing device 170, and other remote systems. The communication stack 120 can enable the local computing device 110 to exchange information remotely over a network, such as through an antenna array or interface that can provide a metropolitan WIFI® network connection, a mobile or cellular network connection (e.g., Third Generation (3G), Fourth Generation (4G), Long-Term Evolution (LTE), 5th Generation (5G), etc.), and/or other wireless network connection (e.g., License Assisted Access (LAA), Citizens Broadband Radio Service (CBRS), MULTEFIRE, etc.). The communication stack 120 can also facilitate local exchange of information, such as through a wired connection (e.g., a user's mobile computing device docked in an in-car docking station or connected via Universal Serial Bus (USB), etc.) or a local wireless connection (e.g., Wireless Local Area Network (WLAN), Bluetooth®, infrared, etc.).

The HD geospatial database 122 can store HD maps and related data of the streets upon which the AV 102 travels. In some embodiments, the HD maps and related data can comprise multiple layers, such as an areas layer, a lanes and boundaries layer, an intersections layer, a traffic controls layer, and so forth. The areas layer can include geospatial information indicating geographic areas that are drivable (e.g., roads, parking areas, shoulders, etc.) or not drivable (e.g., medians, sidewalks, buildings, etc.), drivable areas that constitute links or connections (e.g., drivable areas that form the same road) versus intersections (e.g., drivable areas where two or more roads intersect), and so on. The lanes and boundaries layer can include geospatial information of road lanes (e.g., lane or road centerline, lane boundaries, type of lane boundaries, etc.) and related attributes (e.g., direction of travel, speed limit, lane type, etc.). The lanes and boundaries layer can also include 3D attributes related to lanes (e.g., slope, elevation, curvature, etc.). The intersections layer can include geospatial information of intersections (e.g., crosswalks, stop lines, turning lane centerlines, and/or boundaries, etc.) and related attributes (e.g., permissive, protected/permissive, or protected only left turn lanes; permissive, protected/permissive, or protected only U-turn lanes; permissive or protected only right turn lanes; etc.). The traffic controls layer can include geospatial information of traffic signal lights, traffic signs, and other road objects and related attributes.

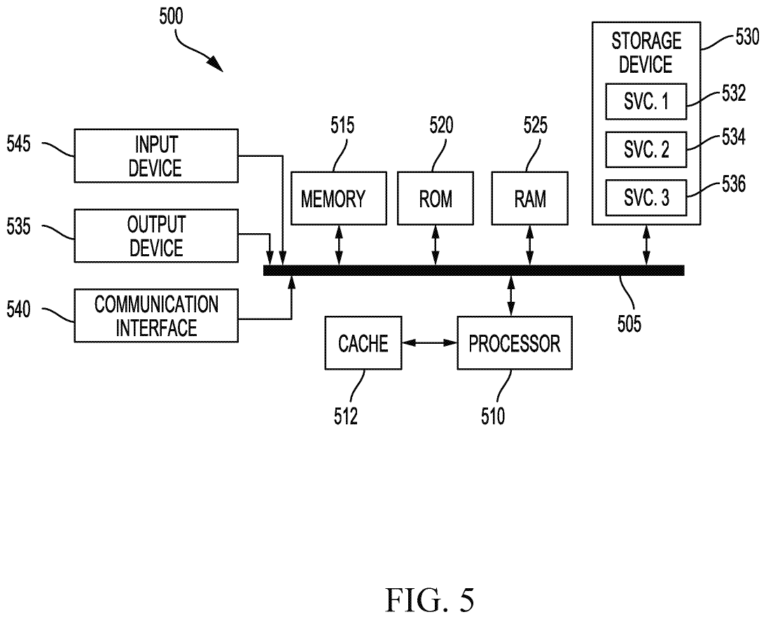

The AV operational database 124 can store raw AV data generated by the sensor systems 104-108 and other components of the AV 102 and/or data received by the AV 102 from remote systems (e.g., the data center 150, the client computing device 170, etc.). In some embodiments, the raw AV data can include HD LIDAR point cloud data, image or video data, RADAR data, GPS data, and other sensor data that the data center 150 can use for creating or updating AV geospatial data as discussed further below with respect to FIG. 5 and elsewhere in the present disclosure.

The data center 150 can be a private cloud (e.g., an enterprise network, a co-location provider network, etc.), a public cloud (e.g., an Infrastructure as a Service (IaaS) network, a Platform as a Service (PaaS) network, a Software as a Service (SaaS) network, or other Cloud Service Provider (CSP) network), a hybrid cloud, a multi-cloud, and so forth. The data center 150 can include one or more computing devices remote to the local computing device 110 for managing a fleet of AVs and AV-related services. For example, in addition to managing the AV 102, the data center 150 may also support a ridesharing service, a delivery service, a remote/roadside assistance service, street services (e.g., street mapping, street patrol, street cleaning, street metering, parking reservation, etc.), and the like.

The data center 150 can send and receive various signals to and from the AV 102 and the client computing device 170. These signals can include sensor data captured by the sensor systems 104-108, roadside assistance requests, software updates, ridesharing pick-up and drop-off instructions, and so forth. In this example, the data center 150 includes one or more of a data management platform 152, an Artificial Intelligence/Machine Learning (AI/ML) platform 154, a simulation platform 156, a remote assistance platform 158, a ridesharing platform 160, and a map management platform 162, among other systems.

Data management platform 152 can be a “big data” system capable of receiving and transmitting data at high speeds (e.g., near real-time or real-time), processing a large variety of data, and storing large volumes of data (e.g., terabytes, petabytes, or more of data). The varieties of data can include data having different structures (e.g., structured, semi-structured, unstructured, etc.), data of different types (e.g., sensor data, mechanical system data, ridesharing service data, map data, audio data, video data, etc.), data associated with different types of data stores (e.g., relational databases, key-value stores, document databases, graph databases, column-family databases, data analytic stores, search engine databases, time series databases, object stores, file systems, etc.), data originating from different sources (e.g., AVs, enterprise systems, social networks, etc.), data having different rates of change (e.g., batch, streaming, etc.), or data having other heterogeneous characteristics. The various platforms and systems of the data center 150 can access data stored by the data management platform 152 to provide their respective services.

The AI/ML platform 154 can provide the infrastructure for training and evaluating machine learning algorithms for operating the AV 102, the simulation platform 156, the remote assistance platform 158, the ridesharing platform 160, the map management platform 162, and other platforms and systems. Using the AI/ML platform 154, data scientists can prepare data sets from the data management platform 152; select, design, and train machine learning models; evaluate, refine, and deploy the models; maintain, monitor, and retrain the models; and so on.

The simulation platform 156 can enable testing and validation of the algorithms, machine learning models, neural networks, and other development efforts for the AV 102, the remote assistance platform 158, the ridesharing platform 160, the map management platform 162, and other platforms and systems. The simulation platform 156 can replicate a variety of driving environments and/or reproduce real-world scenarios from data captured by the AV 102 and from third party sources, including rendering geospatial information and road infrastructure (e.g., streets, lanes, crosswalks, traffic lights, stop signs, etc.) obtained from the map management platform 162; modeling the behavior of other vehicles, bicycles, pedestrians, and other dynamic elements; simulating inclement weather conditions, different traffic scenarios; and so on.

The remote assistance platform 158 can generate and transmit instructions regarding the operation of the AV 102. For example, in response to an output of the AI/ML platform 154 or other system of the data center 150, the remote assistance platform 158 can prepare instructions for one or more stacks or other components of the AV 102.

The ridesharing platform 160 can interact with a customer of a ridesharing service via a ridesharing application 172 executing on the client computing device 170. The client computing device 170 can be any type of computing system, including a server, desktop computer, laptop, tablet, smartphone, smart wearable device (e.g., smart watch; smart eyeglasses or other Head-Mounted Display (HMD); smart ear pods or other smart in-ear, on-ear, or over-ear device; etc.), gaming system, or other general purpose computing device for accessing the ridesharing application 172. The client computing device 170 can be a customer's mobile computing device or a computing device integrated with the AV 102 (e.g., the local computing device 110). The ridesharing platform 160 can receive requests to be picked up or dropped off from the ridesharing application 172 and dispatch the AV 102 for the trip.

Map management platform 162 can provide a set of tools for the manipulation and management of geographic and spatial (geospatial) and related attribute data. The data management platform 152 can receive LIDAR point cloud data, image data (e.g., still image, video, etc.), RADAR data, GPS data, and other sensor data (e.g., raw data) from one or more AVs 102, Unmanned Aerial Vehicles (UAVs), satellites, third-party mapping services, and other sources of geospatially referenced data. The raw data can be processed, and map management platform 162 can render base representations (e.g., tiles (2D), bounding volumes (3D), etc.) of the AV geospatial data to enable users to view, query, label, edit, and otherwise interact with the data. Map management platform 162 can manage workflows and tasks for operating on the AV geospatial data. Map management platform 162 can control access to the AV geospatial data, including granting or limiting access to the AV geospatial data based on user-based, role-based, group-based, task-based, and other attribute-based access control mechanisms. Map management platform 162 can provide version control for the AV geospatial data, such as to track specific changes that (human or machine) map editors have made to the data and to revert changes when necessary. Map management platform 162 can administer release management of the AV geospatial data, including distributing suitable iterations of the data to different users, computing devices, AVs, and other consumers of HD maps. Map management platform 162 can provide analytics regarding the AV geospatial data and related data, such as to generate insights relating to the throughput and quality of mapping tasks.

In some embodiments, the map viewing services of map management platform 162 can be modularized and deployed as part of one or more of the platforms and systems of the data center 150. For example, the AI/ML platform 154 may incorporate the map viewing services for visualizing the effectiveness of various object detection or object classification models, the simulation platform 156 may incorporate the map viewing services for recreating and visualizing certain driving scenarios, the remote assistance platform 158 may incorporate the map viewing services for replaying traffic incidents to facilitate and coordinate aid, the ridesharing platform 160 may incorporate the map viewing services into the client application 172 to enable passengers to view the AV 102 in transit en route to a pick-up or drop-off location, and so on.

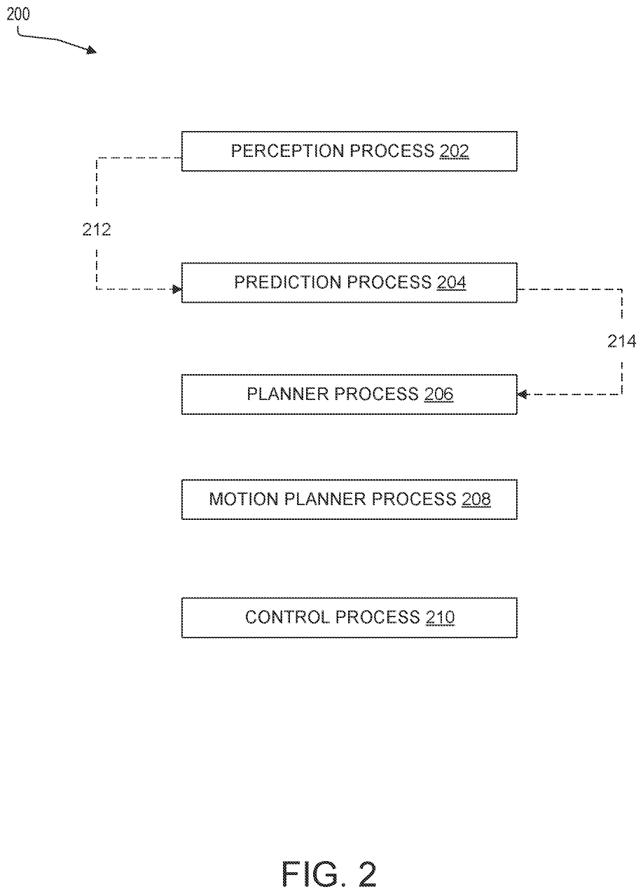

FIG. 2 illustrates a conceptual flow of an AV software stack The example AV software stack shown in FIG. 2 includes applicable processes that can be used in controlling an AV, such as the stacks shown in FIG. 1. Specifically, the example AV software stack shown in FIG. 2 includes a perception process 202, a prediction process 204, a planner process 206, a motion planner process 208, and a control process 210.

The perception process 202 functions to access sensor data gathered by an AV. The perception process 202 can fuse the sensor data. From the sensor data, the perception process 202 can track objects. Specifically, the perception process 202 can identify where tracked objects are in a field of view, e.g. relative to the AV.

The prediction process 204 functions to predict where objects will be in a field of view. Specifically, the prediction process 204 can predict the location of objects that are not tracked by the perception process 202. The prediction process 204 can predict the location of objects based on the tracked object output of the perception process 202.

The planner process 206 functions to identify a path for the AV. Specifically, the planner process 206 functions to identify a path for the AV based on either or both the output of the perception process 202 and the prediction process 204. In identifying a path for the AV, the planner process can weigh various moves by the AV against costs with respect to the output of either or both the perception process 202 and the prediction process 204.

The motion planner process 208 functions to identify a refined path for the AV. In particular, the motion planner process 208 functions to identify a refined path for the AV with respect to the path identified by the planner process 206. A refined path developed by the motion planner process 208 can include a path that is planned according to smaller time operations and smaller distances in comparison to the scheme that is used to develop the path by the planner process 206.

The control process 210 functions to communicate with control systems of the AV to implement the plan developed by either or both the planner process 206 and the motion planner process 208. Specifically, the control process 210 can communicate values of parameters for controlling the AV to applicable systems for controlling the AV. For example, the control process 210 can specify to an acceleration controller of the AV to accelerate at 10%.

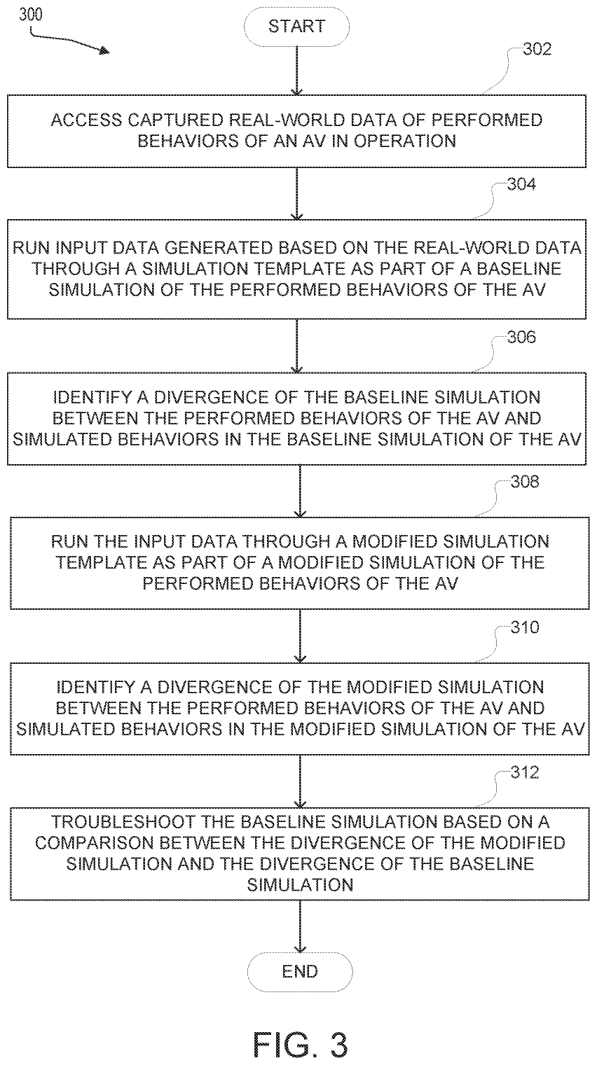

FIG. 3 illustrates a flowchart for an example method of troubleshooting a simulation based on a comparison between the divergence of a modified simulation and the divergence of a baseline simulation. At block 302, the process 300 can include accessing captured real-world data of performed behaviors of an autonomous vehicle (e.g., AV 102) in operation. In some examples, this captured real-world data is subsequently used to run simulations.

Real-world data, otherwise referred to as road bag data, can include the data that is generated on-road during actual operation of the AV. Specifically, real-world data can include raw AV data. Raw AV data can include sensor data that is gathered by sensors as the AV performs various maneuvers in a real-world environment. For example, raw AV data can include data captured by a LIDAR sensor that is indicative of objects surrounding an AV in an environment.

Real-world data can also include data that is generated in running a software stack associated with operation of an AV. Specifically, real-world data can include data that is generated by running all or a portion of the software stacks shown in FIG. 2. For example, real-world data can include an output of running a perception stack. In turn, the output of the perception stack can include an indication of objects in an environment. Specifically, the output of the perception stack can include trajectories of objects in the environment as the objects move, e.g. relative to an AV. For example, real-world data can include a trajectory of a car driving next to an AV in a real-world environment.

At block 304, the process 300 can include running input data that is generated based on the real-world data through a simulation template as part of a baseline simulation of the performed behaviors of the AV. A simulation template includes applicable processes for simulating controlled operation of the AV in a simulated environment. Specifically, a simulation template can include applicable processes in software stacks for controlling operation of an AV, e.g. such as the processes shown in FIG. 2.

A simulation template that is run at block 304 can be different from a software stack that is run in generating the real-world data that is accessed at process 302. In some examples, the simulation template can be modified in order to troubleshoot divergences found in the simulation. The simulation template can include a simulated perception stack, a simulated prediction stack, a simulated planner stack, a simulated motion planner simulated, and a simulated control stack. Any of these simulated stacks can be modified by using predetermined input data, thereby providing output to any of the other simulated stacks that are being tested. By using predetermined input data at one (or more) of the simulated stacks, divergences in the output of other simulated stacks can be more easily identified and isolated. For example, predetermined input data can be used at the simulated prediction stack to more easily identify any causes of divergence in the subsequent simulated stacks (i.e. the simulated planner stack, the simulated motion planner simulated, and/or the simulated control stack). It is contemplated that predetermined input data can be input at any simulated stack that will aid in troubleshooting divergences.

At block 306, the process 300 can include identifying a divergence of the baseline simulation between the performed behaviors of the AV and simulated behaviors in the baseline simulation of the AV. Divergence can be based on the differences in the simulation template that is run at block 304 and the processes that are run in generating the real-world data. For example, a difference between the location where the AV stopped in a real world environment and the location where the simulated AV stopped can be a divergence. A larger distance between the stopping locations of the real world AV and the simulated AV indicated a larger divergence. Any measurable attribute that can be compared between the operation of the AV and the simulated AV can result in a divergence. Other examples of measurable attributes include, but are not limited to, comparison of AV decisions (i.e. whether to turn, whether to stop, whether to accelerate, etc.), speed, acceleration, pose, and any other measurable attribute.

Divergence can be identified using an applicable technique for determining differences between one or more aspects of simulations in comparison to either or both other simulations or the process of generating the real-world data. In some examples, the divergence of the baseline simulation is based on a control output of the baseline simulation and a control output of the performed behaviors of the AV. In some examples, the divergence of the modified simulation is based on a control output of the modified simulation and the control output of the performed behaviors of the AV. For example, divergence can be identified based on differences in a trajectory of the AV that is generated by running the software stacks to completion through the control process.

In some examples, the divergence of the baseline simulation is based on an output of a subprocess of the baseline simulation and an output of the subprocess that is run in generating the real-world data. Specifically, divergence can be measured based an output of corresponding software stacks that are run in simulation and/or in generation of the real-world data. For example, and as will be discussed in greater detail later, the output of the planner process 206 can be compared across different simulations to identify divergence between the simulations. In another example, the output of the motion planner process 208 in generating the real-world bag data can be compared to the output of the motion planner process 208 in running the baseline simulation to identify the divergence between the baseline simulation and captured real-world data.

Divergence can also be due to the non-deterministic nature of the software stack in both the simulation template and the processes used in generated the real-world data. Non-determinism is the concept that the same software stack can be provided the same input and generate different output as it is run different times. The processes, e.g. the processes in FIG. 2, that are run in generating the real-world bag data and run as part of simulation templates can create varying output based on divergence. For example, the baseline simulation and a modified simulation, as will be discussed in greater detail later, can have divergence do to the non-deterministic nature of the software stacks that form corresponding simulation templates. Similarly, divergence between the baseline simulation and the performed behaviors associated with the captured real-world data can be due to the non-deterministic nature of the software stacks that form the baseline simulation template and the software stacks that are run in controlling the AV to perform the real-world behaviors.

In some examples, the identified divergence between the performed behaviors of the AV and simulated behaviors in the baseline simulation of the AV can include the AVs stopping at different locations, making different decisions, differences in velocity or acceleration, and different pose, among other identified divergences. In some examples, determining the cause of this divergence can include identifying whether one or more processes are the cause of the divergence of the baseline simulation.

In some examples, the divergence of the modified simulation is based on a control output of the modified simulation and the control output of the performed behaviors of the AV. In some examples, the divergence of the baseline simulation is based on an output of a subprocess of the baseline simulation and an output of the subprocess corresponding to the performed behaviors of the AV. In some examples, the divergence of the modified simulation is based on an output of the subprocess of the modified simulation and the output of the subprocess corresponding to the performed behaviors of the AV. In some examples, identifying whether one or more processes are a cause of the divergence of the baseline simulation can be based on excluding one or more processes from the modified simulation and comparing between the divergence of the baseline simulation and the divergence of the modified simulation.

At block 308, the process 300 can include running the input data through a modified simulation template as part of a modified simulation of the performed behaviors of the AV. In some examples, processes can be grouped together in the simulation template into an organizational structure of software stacks to identify one or more processes to remove from the simulation template based on the organizational structure of the software stacks. For example, the simulated perception stack and the simulated prediction stack can be grouped together in the modified simulation template in order to troubleshoot the simulated planner stack, the simulated motion planner simulated, and the simulated control stack. In such an example, predetermined input data can be substituted for the grouped simulated perception stack and simulated prediction stack in order to isolate them from the simulated planner stack, the simulated motion planner simulated, and the simulated control stack and determine whether the identified divergence is caused by the simulated planner stack, the simulated motion planner simulated, and/or the simulated control stack. In other examples, any of the processes can be grouped together in this manner to troubleshoot and isolate the identified divergence.

In some examples, the divergence of the modified simulation is based on a control output of the modified simulation and the control output of the performed behaviors of the AV. In some examples, the divergence of the baseline simulation is based on an output of a subprocess of the baseline simulation and an output of the subprocess corresponding to the performed behaviors of the AV. In some examples, the divergence of the modified simulation is based on an output of the subprocess of the modified simulation and the output of the subprocess corresponding to the performed behaviors of the AV. In some examples, identifying whether one or more processes are a cause of the divergence of the baseline simulation can be based on excluding one or more processes from the modified simulation and comparing between the divergence of the baseline simulation and the divergence of the modified simulation.

In some examples, the simulation template can be modified to create the modified simulation template by removing one or more processes from the simulation template. In some examples, the one or more processes can be removed from the simulation template selectively. In other examples, the one or more processes can be removed from the simulation template randomly. The processes can include the simulated perception stack, the simulated prediction stack, the simulated planner stack, the simulated motion planner simulated, and the simulated control stack. In this example, the processes interact with each other in a downstream manner wherein the output of the simulated perception stack is input into the simulated prediction stack, and subsequently, the output of the simulated prediction stack is input into the simulated planner stack, etc. as illustrated and discussed with reference to FIG. 2 above. A process can be individually removed, or processes can be grouped together and removed. Since the processes operate in a downstream manner, removing a process can require replacing the process with predetermined data so that the remaining processes can be analyzed to troubleshoot the identified divergence. In some examples, a process (or group of processes) can first be removed and subsequently replaced back while a different process (or group of processes) is removed until the cause of the identified divergences can be determined.

At block 310, the process 300 can include identifying a divergence of the modified simulation between the performed behaviors of the AV and simulated behaviors in the modified simulation of the AV. Divergence can be based on the differences in the modified simulation template that is run at block 308 and the processes that are run in generating the real-world data. In some examples, the divergences identified between the performed behaviors of the AV and simulated behaviors in the modified simulation of the AV can be the same divergences identified between the performed behaviors of the AV and simulated behaviors in the baseline simulation of the AV discussed above. For example, a difference between the stopping locations of the real world AV and the simulated AV. Additionally, any measurable attribute that can be compared between the operation of the AV and the simulated AV can result in a divergence. Other examples of measurable attributes include, but are not limited to, comparison of AV decisions (i.e. whether to turn, whether to stop, whether to accelerate, etc.), speed, acceleration, pose, and any other measurable attribute.

Divergence between the modified simulation and the performed behaviors of the AV can be measured through an applicable technique, such as the techniques described herein. In some examples, the divergence of the modified simulation is based on an output of the subprocess of the modified simulation and the output of the subprocess corresponding to the performed behaviors of the AV. In some examples, identifying whether one or more processes are a cause of the divergence of the baseline simulation can be based on excluding one or more processes from the modified simulation and comparing between the divergence of the baseline simulation and the divergence of the modified simulation.

At block 312, the process 300 can include troubleshooting the baseline simulation based on a comparison between the divergence of the modified simulation and the divergence of the baseline simulation. Specifically, the divergence of the modified simulation and the divergence of the baseline simulation can be compared to see if the modified simulation reduced the amount of divergence relative to the real-world data. In turn, the baseline simulation can be modified based on the comparison between the divergence of the modified simulation and the divergence of the baseline simulation, e.g. as part of troubleshooting the baseline simulation. For example, the baseline simulation can be modified based on the modifications to the template that were made in generating and running the modified simulation template, if the modified simulation has a decreased divergence relative to the divergence of the baseline simulation.

In troubleshooting the baseline simulation template, processes corresponding to the modified simulation template can be modified in the baseline simulation template. For example, a divergence between the baseline simulation and the corresponding real-world data can be 5%. Further in the example, the baseline simulation template can be modified to create the modified simulation template by removing processes from the perception process. As follows, the modified simulation template can be run in the modified simulation and have only a 3% divergence from the real-world data. In turn, the perception process in the baseline simulation template can be modified based on the observed reduction in divergence.

Troubleshooting the baseline simulation template based on a comparison between the divergence of the modified simulation and the divergence of the baseline simulation can factoring in non-determinism in running either or both the baseline simulation and the modified simulation. Specifically, it can be determined whether one or more processes that are removed from the baseline simulation to generate the modified simulation or non-determinism is a source of the divergence between the baseline simulation and the real-world data. More specifically, this determination can be made based on both the exclusion of the one or more processes from the modified simulation and the comparison between the divergence of the baseline simulation and the divergence of the modified simulation. For example, one or more processes from the planner process can be removed from the baseline simulation template to generate the modified simulation template. As a result of removal of these processes, the modified simulation should either have the same divergence as the baseline simulation or less divergence than the baseline simulation. However, if the modified simulation has an increased divergence in comparison to the baseline simulation relative to the real-world data, then this divergence can be attributed to non-determinism. As follows, the baseline simulation can be troubleshooted based on non-determinism being the source of the divergence. Specifically, the planner process in the baseline template can be left unmodified as they are potentially not contributing to the baseline divergence.

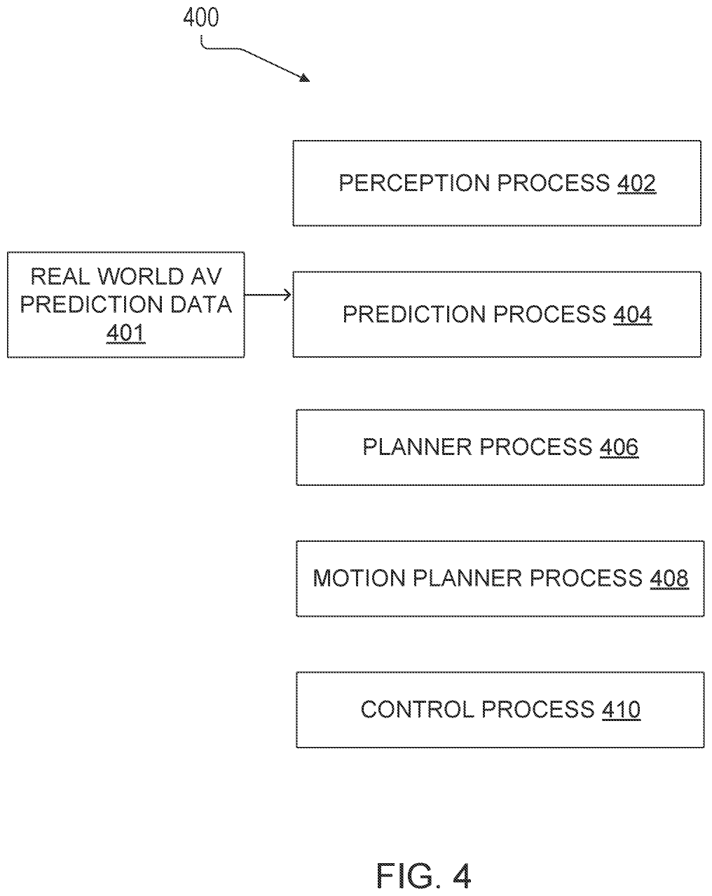

FIG. 4 illustrates a conceptual flow of incrementing a subset of a simulated AV software stack, according to another example of the present disclosure. Like FIG. 2, the example simulated AV software stack shown in FIG. 4 includes applicable processes that can be used in controlling an simulated AV. Specifically, the example simulated AV software stack shown in FIG. 4 includes a perception process 402, a prediction process 404, a planner process 406, a motion planner process 408, and a control process 410. Further, FIG. 4 includes real world AV prediction data 401, which can be the output of the prediction process 204 that is run in the real-world to control the AV. In the example where the simulated prediction process 404 is removed (as discussed previously), this prediction data 401 can be used in place of the prediction process 404. Replacing the simulated prediction process 404 with the real world AV prediction data 401 can help isolate the cause of the divergence if the cause if suspected to be in one of the other processes.

As discussed previously, in operation (at step 308) the process 300 can include running the input data through a modified simulation template as part of a modified simulation of the performed behaviors of the AV. In some examples, the simulation is modified by inputting a subset of the collected real-world AV data into the simulated AV software stack shown in FIG. 4 at one of the stacks (i.e. perception process 402, prediction process 404, planner process 406, motion planner process 408, or control process 410). For example, as shown in FIG. 4, the real-world AV prediction data 401 can be input into the simulation prediction process 404. In some examples, this real-world AV prediction data 401 can then be used by the subsequent simulated stacks (i.e. planner process 406, motion planner process 408, or control process 410) and the results analyzed to determine a divergence. In this way it is possible to isolate potential causes of the divergence. The example shown in FIG. 4 is only one example, and it is additionally possible to input real-world AV data into any of the simulated stacks (i.e. perception process 402, prediction process 404, planner process 406, motion planner process 408, and control process 410) to determine the cause of a divergence.

FIG. 5 illustrates an example processor-based system with which some aspects of the subject technology can be implemented. For example, processor-based system 500 can be any computing device making up, or any component thereof in which the components of the system are in communication with each other using connection 505. Connection 505 can be a physical connection via a bus, or a direct connection into processor 510, such as in a chipset architecture. Connection 505 can also be a virtual connection, networked connection, or logical connection.

In some embodiments, computing system 500 is a distributed system in which the functions described in this disclosure can be distributed within a datacenter, multiple data centers, a peer network, etc. In some embodiments, one or more of the described system components represents many such components each performing some or all of the function for which the component is described. In some embodiments, the components can be physical or virtual devices.

Example system 500 includes at least one processing unit (Central Processing Unit (CPU) or processor) 510 and connection 505 that couples various system components including system memory 515, such as Read-Only Memory (ROM) 520 and Random-Access Memory (RAM) 525 to processor 510. Computing system 500 can include a cache of high-speed memory 512 connected directly with, in close proximity to, or integrated as part of processor 510.

Processor 510 can include any general-purpose processor and a hardware service or software service, such as services 532, 534, and 536 stored in storage device 530, configured to control processor 510 as well as a special-purpose processor where software instructions are incorporated into the actual processor design. Processor 510 may essentially be a completely self-contained computing system, containing multiple cores or processors, a bus, memory controller, cache, etc. A multi-core processor may be symmetric or asymmetric.

To enable user interaction, computing system 500 includes an input device 545, which can represent any number of input mechanisms, such as a microphone for speech, a touch-sensitive screen for gesture or graphical input, keyboard, mouse, motion input, speech, etc. Computing system 500 can also include output device 535, which can be one or more of a number of output mechanisms known to those of skill in the art. In some instances, multimodal systems can enable a user to provide multiple types of input/output to communicate with computing system 500. Computing system 500 can include communications interface 540, which can generally govern and manage the user input and system output. The communication interface may perform or facilitate receipt and/or transmission wired or wireless communications via wired and/or wireless transceivers, including those making use of an audio jack/plug, a microphone jack/plug, a Universal Serial Bus (USB) port/plug, an Apple® Lightning® port/plug, an Ethernet port/plug, a fiber optic port/plug, a proprietary wired port/plug, a BLUETOOTH® wireless signal transfer, a BLUETOOTH® low energy (BLE) wireless signal transfer, an IBEACON® wireless signal transfer, a Radio-Frequency Identification (RFID) wireless signal transfer, Near-Field Communications (NFC) wireless signal transfer, Dedicated Short Range Communication (DSRC) wireless signal transfer, 802.11 Wi-Fi® wireless signal transfer, Wireless Local Area Network (WLAN) signal transfer, Visible Light Communication (VLC) signal transfer, Worldwide Interoperability for Microwave Access (WiMAX), Infrared (IR) communication wireless signal transfer, Public Switched Telephone Network (PSTN) signal transfer, Integrated Services Digital Network (ISDN) signal transfer, 3G/4G/5G/LTE cellular data network wireless signal transfer, ad-hoc network signal transfer, radio wave signal transfer, microwave signal transfer, infrared signal transfer, visible light signal transfer signal transfer, ultraviolet light signal transfer, wireless signal transfer along the electromagnetic spectrum, or some combination thereof.

Communication interface 540 may also include one or more Global Navigation Satellite System (GNSS) receivers or transceivers that are used to determine a location of the computing system 500 based on receipt of one or more signals from one or more satellites associated with one or more GNSS systems. GNSS systems include, but are not limited to, the US-based Global Positioning System (GPS), the Russia-based Global Navigation Satellite System (GLONASS), the China-based BeiDou Navigation Satellite System (BDS), and the Europe-based Galileo GNSS. There is no restriction on operating on any particular hardware arrangement, and therefore the basic features here may easily be substituted for improved hardware or firmware arrangements as they are developed.

Storage device 530 can be a non-volatile and/or non-transitory and/or computer-readable memory device and can be a hard disk or other types of computer readable media which can store data that are accessible by a computer, such as magnetic cassettes, flash memory cards, solid state memory devices, digital versatile disks, cartridges, a floppy disk, a flexible disk, a hard disk, magnetic tape, a magnetic strip/stripe, any other magnetic storage medium, flash memory, memristor memory, any other solid-state memory, a Compact Disc (CD) Read Only Memory (CD-ROM) optical disc, a rewritable CD optical disc, a Digital Video Disk (DVD) optical disc, a Blu-ray Disc (BD) optical disc, a holographic optical disk, another optical medium, a Secure Digital (SD) card, a micro SD (microSD) card, a Memory Stick® card, a smartcard chip, a EMV chip, a Subscriber Identity Module (SIM) card, a mini/micro/nano/pico SIM card, another Integrated Circuit (IC) chip/card, Random-Access Memory (RAM), Atatic RAM (SRAM), Dynamic RAM (DRAM), Read-Only Memory (ROM), Programmable ROM (PROM), Erasable PROM (EPROM), Electrically Erasable PROM (EEPROM), flash EPROM (FLASHEPROM), cache memory (L1/L2/L3/L4/L5/L#), Resistive RAM (RRAM/ReRAM), Phase Change Memory (PCM), Spin Transfer Torque RAM (STT-RAM), another memory chip or cartridge, and/or a combination thereof.

Storage device 530 can include software services, servers, services, etc., that when the code that defines such software is executed by the processor 510, it causes the system 500 to perform a function. In some embodiments, a hardware service that performs a particular function can include the software component stored in a computer-readable medium in connection with the necessary hardware components, such as processor 510, connection 505, output device 535, etc., to carry out the function.

Embodiments within the scope of the present disclosure may also include tangible and/or non-transitory computer-readable storage media or devices for carrying or having computer-executable instructions or data structures stored thereon. Such tangible computer-readable storage devices can be any available device that can be accessed by a general purpose or special purpose computer, including the functional design of any special purpose processor as described above. By way of example, and not limitation, such tangible computer-readable devices can include RAM, ROM, EEPROM, CD-ROM or other optical disk storage, magnetic disk storage or other magnetic storage devices, or any other device which can be used to carry or store desired program code in the form of computer-executable instructions, data structures, or processor chip design. When information or instructions are provided via a network or another communications connection (either hardwired, wireless, or combination thereof) to a computer, the computer properly views the connection as a computer-readable medium. Thus, any such connection is properly termed a computer-readable medium. Combinations of the above should also be included within the scope of the computer-readable storage devices.

Computer-executable instructions include, for example, instructions and data which cause a general-purpose computer, special purpose computer, or special purpose processing device to perform a certain function or group of functions. Computer-executable instructions also include program modules that are executed by computers in stand-alone or network environments. Generally, program modules include routines, programs, components, data structures, objects, and the functions inherent in the design of special-purpose processors, etc. that perform tasks or implement abstract data types. Computer-executable instructions, associated data structures, and program modules represent examples of the program code means for executing operations of the methods disclosed herein. The particular sequence of such executable instructions or associated data structures represents examples of corresponding acts for implementing the functions described in such operations.

Other embodiments of the disclosure may be practiced in network computing environments with many types of computer system configurations, including personal computers, hand-held devices, multi-processor systems, microprocessor-based or programmable consumer electronics, network Personal Computers (PCs), minicomputers, mainframe computers, and the like. Embodiments may also be practiced in distributed computing environments where tasks are performed by local and remote processing devices that are linked (either by hardwired links, wireless links, or by a combination thereof) through a communications network. In a distributed computing environment, program modules may be located in both local and remote memory storage devices.

The various embodiments described above are provided by way of illustration only and should not be construed to limit the scope of the disclosure. For example, the principles herein apply equally to optimization as well as general improvements. Various modifications and changes may be made to the principles described herein without following the example embodiments and applications illustrated and described herein, and without departing from the spirit and scope of the disclosure. Claim language reciting “at least one of” a set indicates that one member of the set or multiple members of the set satisfy the claim.

Claim language or other language in the disclosure reciting “at least one of” a set and/or “one or more” of a set indicates that one member of the set or multiple members of the set (in any combination) satisfy the claim. For example, claim language reciting “at least one of A and B” or “at least one of A or B” means A, B, or A and B. In another example, claim language reciting “at least one of A, B, and C” or “at least one of A, B, or C” means A, B, C, or A and B, or A and C, or B and C, or A and B and C. The language “at least one of” a set and/or “one or more” of a set does not limit the set to the items listed in the set. For example, claim language reciting “at least one of A and B” or “at least one of A or B” can mean A, B, or A and B, and can additionally include items not listed in the set of A and B.

Illustrative examples of the disclosure include:

Aspect 1. A method comprising: accessing captured real-world data of performed behaviors of an autonomous vehicle (AV) in operation; running input data that is generated based on the real-world data through a simulation template as part of a baseline simulation of the performed behaviors of the AV; identifying a divergence of the baseline simulation between the performed behaviors of the AV and simulated behaviors in the baseline simulation of the AV; running the input data through a modified simulation template as part of a modified simulation of the performed behaviors of the AV; identifying a divergence of the modified simulation between the performed behaviors of the AV and simulated behaviors in the modified simulation of the AV; and troubleshooting the baseline simulation based on a comparison between the divergence of the modified simulation and the divergence of the baseline simulation.

Aspect 2. The method of Aspect 1, wherein the simulation template is modified to create the modified simulation template by removing one or more processes from the simulation template.

Aspect 3. The method of Aspect 2, further comprising identifying whether the one or more processes are a cause of the divergence of the baseline simulation, as part of troubleshooting the baseline simulation, based on: an exclusion of the one or more processes from the modified simulation; and the comparison between the divergence of the baseline simulation and the divergence of the modified simulation.

Aspect 4. The method of Aspect 2 or 3, further comprising identifying whether the one or more processes or non-determinism in running the baseline simulation are a cause of the divergence of the baseline simulation, as part of troubleshooting the baseline simulation, based on: an exclusion of the one or more processes from the modified simulation; and the comparison between the divergence of the baseline simulation and the divergence of the modified simulation.

Aspect 5. The method of any of Aspects 2 to 4, further comprising: grouping processes in the simulation template into an organizational structure of software stacks run in controlling the AV; and identifying the one or more processes to remove from the simulation template based on the organizational structure of the software stacks.

Aspect 6. The method of any of Aspects 1 to 5, wherein either or both: the divergence of the baseline simulation is based on a control output of the baseline simulation and a control output of the performed behaviors of the AV; and the divergence of the modified simulation is based on a control output of the modified simulation and the control output of the performed behaviors of the AV.

Aspect 7. The method of any of Aspects 1 to 6, wherein either or both: the divergence of the baseline simulation is based on an output of a subprocess of the baseline simulation and an output of the subprocess corresponding to the performed behaviors of the AV; and the divergence of the modified simulation is based on an output of the subprocess of the modified simulation and the output of the subprocess corresponding to the performed behaviors of the AV.

Aspect 8. The method of any of Aspects 1 to 7, further comprising modifying the baseline simulation template based on the comparison between the divergence of the modified simulation and the divergence of the baseline simulation as part of troubleshooting the baseline simulation.

Aspect 9. The method of any of Aspects 1 to 8, wherein the simulation template is a new version of a previous simulation template.

Aspect 10. A system comprising: one or more processors; and at least one computer-readable storage medium having stored therein instructions which, when executed by the one or more processors, cause the one or more processors to: access captured real-world data of performed behaviors of an autonomous vehicle (AV) in operation; run input data that is generated based on the real-world data through a simulation template as part of a baseline simulation of the performed behaviors of the AV; identify a divergence of the baseline simulation between the performed behaviors of the AV and simulated behaviors in the baseline simulation of the AV; run the input data through a modified simulation template as part of a modified simulation of the performed behaviors of the AV; identify a divergence of the modified simulation between the performed behaviors of the AV and simulated behaviors in the modified simulation of the AV; and troubleshoot the baseline simulation based on a comparison between the divergence of the modified simulation and the divergence of the baseline simulation.

Aspect 11. The system of Aspect 10, wherein the simulation template is modified to create the modified simulation template by removing one or more processes from the simulation template.

Aspect 12. The system of Aspect 11, wherein the instructions further cause the one or more processors to identify whether the one or more processes are a cause of the divergence of the baseline simulation, as part of troubleshooting the baseline simulation, based on: an exclusion of the one or more processes from the modified simulation; and the comparison between the divergence of the baseline simulation and the divergence of the modified simulation.

Aspect 13. The system of Aspect 11 or 12, wherein the instructions further cause the one or more processors to identify whether the one or more processes or non-determinism in running the baseline simulation are a cause of the divergence of the baseline simulation, as part of troubleshooting the baseline simulation, based on: an exclusion of the one or more processes from the modified simulation; and the comparison between the divergence of the baseline simulation and the divergence of the modified simulation.

Aspect 14. The system of any of Aspects 11 to 13, wherein the instructions further cause the one or more processors to: group processes in the simulation template into an organizational structure of software stacks run in controlling the AV; and identify the one or more processes to remove from the simulation template based on the organizational structure of the software stacks.

Aspect 15. The system of any of Aspects 10 to 14, wherein either or both: the divergence of the baseline simulation is based on a control output of the baseline simulation and a control output of the performed behaviors of the AV; and the divergence of the modified simulation is based on a control output of the modified simulation and the control output of the performed behaviors of the AV.

Aspect 16. The system of any of Aspects 10 to 15, wherein either or both: the divergence of the baseline simulation is based on an output of a subprocess of the baseline simulation and an output of the subprocess corresponding to the performed behaviors of the AV; and the divergence of the modified simulation is based on an output of the subprocess of the modified simulation and the output of the subprocess corresponding to the performed behaviors of the AV.

Aspect 17. The system of any of Aspects 10 to 16, wherein the instructions further cause the one or more processors to modify the baseline simulation template based on the comparison between the divergence of the modified simulation and the divergence of the baseline simulation as part of troubleshooting the baseline simulation.

Aspect 18. The system of any of Aspects 10 to 17, wherein the simulation template is a new version of a previous simulation template.

Aspect 19. A non-transitory computer-readable storage medium having stored therein instructions which, when executed by one or more processors, cause the one or more processors to: access captured real-world data of performed behaviors of an autonomous vehicle (AV) in operation; run input data that is generated based on the real-world data through a simulation template as part of a baseline simulation of the performed behaviors of the AV; identify a divergence of the baseline simulation between the performed behaviors of the AV and simulated behaviors in the baseline simulation of the AV; run the input data through a modified simulation template as part of a modified simulation of the performed behaviors of the AV; identify a divergence of the modified simulation between the performed behaviors of the AV and simulated behaviors in the modified simulation of the AV; and troubleshoot the baseline simulation based on a comparison between the divergence of the modified simulation and the divergence of the baseline simulation.

Aspect 20. The non-transitory computer-readable storage medium of Aspect 19, wherein the simulation template is modified to create the modified simulation template by removing one or more processes from the simulation template and the instructions further cause the one or more processors to identify whether the one or more processes are a cause of the divergence of the baseline simulation, as part of troubleshooting the baseline simulation, based on: an exclusion of the one or more processes from the modified simulation; and the comparison between the divergence of the baseline simulation and the divergence of the modified simulation.

Aspect 21. A system comprising means for performing a method according to any of Aspects 1 through 9.

What is claimed is:

1. A method comprising:
accessing captured real-world data of performed behaviors of an autonomous vehicle (AV) in operation;
running input data that is generated based on the real-world data through a simulation template as part of a baseline simulation of the performed behaviors of the AV;
identifying a divergence of the baseline simulation between the performed behaviors of the AV and simulated behaviors in the baseline simulation of the AV;
running the input data through a modified simulation template as part of a modified simulation of the performed behaviors of the AV;
identifying a divergence of the modified simulation between the performed behaviors of the AV and simulated behaviors in the modified simulation of the AV; and
troubleshooting the baseline simulation based on a comparison between the divergence of the modified simulation and the divergence of the baseline simulation.

2. The method of claim 1, wherein the simulation template is modified to create the modified simulation template by removing one or more processes from the simulation template.

3. The method of claim 2, further comprising identifying whether the one or more processes are a cause of the divergence of the baseline simulation, as part of troubleshooting the baseline simulation, based on:
an exclusion of the one or more processes from the modified simulation; and
the comparison between the divergence of the baseline simulation and the divergence of the modified simulation.

4. The method of claim 2, further comprising identifying whether the one or more processes or non-determinism in running the baseline simulation are a cause of the divergence of the baseline simulation, as part of troubleshooting the baseline simulation, based on:
an exclusion of the one or more processes from the modified simulation; and
the comparison between the divergence of the baseline simulation and the divergence of the modified simulation.

5. The method of claim 2, further comprising:
grouping processes in the simulation template into an organizational structure of software stacks run in controlling the AV; and
identifying the one or more processes to remove from the simulation template based on the organizational structure of the software stacks.

6. The method of claim 1, wherein either or both:
the divergence of the baseline simulation is based on a control output of the baseline simulation and a control output of the performed behaviors of the AV; and
the divergence of the modified simulation is based on a control output of the modified simulation and the control output of the performed behaviors of the AV.

7. The method of claim 1, wherein either or both:
the divergence of the baseline simulation is based on an output of a subprocess of the baseline simulation and an output of the subprocess corresponding to the performed behaviors of the AV; and
the divergence of the modified simulation is based on an output of the subprocess of the modified simulation and the output of the subprocess corresponding to the performed behaviors of the AV.

8. The method of claim 1, further comprising modifying the baseline simulation template based on the comparison between the divergence of the modified simulation and the divergence of the baseline simulation as part of troubleshooting the baseline simulation.

9. The method of claim 1, wherein the simulation template is a new version of a previous simulation template.

10. A system comprising:
one or more processors; and
at least one computer-readable storage medium having stored therein instructions which, when executed by the one or more processors, cause the one or more processors to:
access captured real-world data of performed behaviors of an autonomous vehicle (AV) in operation;
run input data that is generated based on the real-world data through a simulation template as part of a baseline simulation of the performed behaviors of the AV;
identify a divergence of the baseline simulation between the performed behaviors of the AV and simulated behaviors in the baseline simulation of the AV;
run the input data through a modified simulation template as part of a modified simulation of the performed behaviors of the AV;
identify a divergence of the modified simulation between the performed behaviors of the AV and simulated behaviors in the modified simulation of the AV; and
troubleshoot the baseline simulation based on a comparison between the divergence of the modified simulation and the divergence of the baseline simulation.

11. The system of claim 10, wherein the simulation template is modified to create the modified simulation template by removing one or more processes from the simulation template.

12. The system of claim 11, wherein the instructions further cause the one or more processors to identify whether the one or more processes are a cause of the divergence of the baseline simulation, as part of troubleshooting the baseline simulation, based on:
an exclusion of the one or more processes from the modified simulation; and
the comparison between the divergence of the baseline simulation and the divergence of the modified simulation.

13. The system of claim 11, wherein the instructions further cause the one or more processors to identify whether the one or more processes or non-determinism in running the baseline simulation are a cause of the divergence of the baseline simulation, as part of troubleshooting the baseline simulation, based on:
an exclusion of the one or more processes from the modified simulation; and
the comparison between the divergence of the baseline simulation and the divergence of the modified simulation.

14. The system of claim 11, wherein the instructions further cause the one or more processors to:
group processes in the simulation template into an organizational structure of software stacks run in controlling the AV; and
identify the one or more processes to remove from the simulation template based on the organizational structure of the software stacks.

15. The system of claim 10, wherein either or both:
the divergence of the baseline simulation is based on a control output of the baseline simulation and a control output of the performed behaviors of the AV; and
the divergence of the modified simulation is based on a control output of the modified simulation and the control output of the performed behaviors of the AV.

16. The system of claim 10, wherein either or both:
the divergence of the baseline simulation is based on an output of a subprocess of the baseline simulation and an output of the subprocess corresponding to the performed behaviors of the AV; and
the divergence of the modified simulation is based on an output of the subprocess of the modified simulation and the output of the subprocess corresponding to the performed behaviors of the AV.

17. The system of claim 10, wherein the instructions further cause the one or more processors to modify the baseline simulation template based on the comparison between the divergence of the modified simulation and the divergence of the baseline simulation as part of troubleshooting the baseline simulation.

18. The system of claim 10, wherein the simulation template is a new version of a previous simulation template.

19. A non-transitory computer-readable storage medium having stored therein instructions which, when executed by one or more processors, cause the one or more processors to:
access captured real-world data of performed behaviors of an autonomous vehicle (AV) in operation;
run input data that is generated based on the real-world data through a simulation template as part of a baseline simulation of the performed behaviors of the AV;
identify a divergence of the baseline simulation between the performed behaviors of the AV and simulated behaviors in the baseline simulation of the AV;
run the input data through a modified simulation template as part of a modified simulation of the performed behaviors of the AV;
identify a divergence of the modified simulation between the performed behaviors of the AV and simulated behaviors in the modified simulation of the AV; and
troubleshoot the baseline simulation based on a comparison between the divergence of the modified simulation and the divergence of the baseline simulation.

20. The non-transitory computer-readable storage medium of claim 19, wherein the simulation template is modified to create the modified simulation template by removing one or more processes from the simulation template and the instructions further cause the one or more processors to identify whether the one or more processes are a cause of the divergence of the baseline simulation, as part of troubleshooting the baseline simulation, based on:
an exclusion of the one or more processes from the modified simulation; and
the comparison between the divergence of the baseline simulation and the divergence of the modified simulation.
